(19) United States
(12) Patent Application Publication
(10) Pub. No.: US 2013/0070427 A1
(43) Pub. Date: Mar. 21, 2013

(54) Pre molded can package

(71) Applicant: Chung Hsing TZU, Taipei County (TW)

(72) Inventor: Chung Hsing TZU, Taipei County (TW)

(73) Assignee: Great Team Backend Foundry, Inc., British Virgin Islands (GB)

(21) Appl. No.: 13/543,843

(22) Filed: Jul. 8, 2012

Related U.S. Application Data
(60) Provisional application No. 61/505,548, filed on Jul. 8, 2011.

(51) Int. Cl. H05K 5/00

(52) U.S. Cl. CPC H05K 5/0091
USPC 361/736

(57) ABSTRACT

A pre molded can package includes a circuit board, a MEMS die, a pre mold cavity and a can. The MEMS dies are connected to the circuit board by conductive wires and the MEMS dies are separated by the pre mold cavities. A cap is connected to the top of each pre mold cavity to form MEMS die units. The MEMS die units are packed to as to reduce their volume. The manufacturing cost is reduced and the processes are simplified. The MEMS die units are able to be applied to the smaller and fine electronic devices.

### FIELD OF THE INVENTION

The present invention relates to a pre molded can package, and more particularly, to a micro electro-magnetic system die (MEMS die) package which prevents the MEMS die from being interfered by exterior electro-magnetic radiation, light and physical damage to increase the yield rate.

### BACKGROUND OF THE INVENTION

The conventional way for MEMS die package is disclosed in Taiwan Patent No. 1324890 as show in attachment 1, the conventional way for MEMS die package needs two processes which consumes time and wastes material, and has high manufacturing cost. The space for the conductive wires is not sufficient so that the defect rate is high and the volume is bulky.

As shown in FIG. 1 which is developed to improve the shortcomings of the conventional way for MEMS die package, and comprises circuit board 100, a MEMS die 400, a conductive wire 401 which is welded between the circuit board 100 and the MEMS die 400. A can 500 is a hollow can and has two can supporting bars 501, the can 500 is mounted to the circuit board 100 and accommodates the MEMS die 400 on the circuit board 100. By using the epoxy compound to pack the MEMS die 400 on the circuit board 100 so as to form the MEMS die unit 700. However, the MEMS die unit 700 is bulky which cannot be used in the latest electronic devices.

The present invention intends to provide a pre molded can package which improves the shortcomings of the conventional MEMS die unit and can be used in the latest electronic devices.

### SUMMARY OF THE INVENTION

The present invention relates to a pre molded can package and comprises a circuit board, a MEMS die, a pre mold cavity and a can. The MEMS dies are connected to the circuit board by conductive wires and the MEMS dies are separated by the pre mold cavities. A cap is connected to the top of each pre mold cavity to form MEMS die units. The MEMS die units are packed to as to reduce their volume. The manufacturing cost is reduced and the processes are simplified. The MEMS die units are able to be applied to the smaller and fine electronic devices. The present invention prevents the MEMS die from being interfered by exterior electro-magnetic radiation, light and physical damage to increase the yield rate.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows the cross sectional view to show the conventional MEMS die units;

FIG. 2 is a cross sectional view to show the MEMS die units packed by the pre molded can package of the present invention;

FIG. 3 shows the cross sectional view of the MEMS die units located in the compound mold;

FIG. 4 shows the cross sectional view of the MEMS die units which are packed by the pre molded can package of the present invention;

FIG. 5 shows the cross sectional view of each of the MEMS die units which are packed and cut, and

FIG. 6 shows the second embodiment of the pre molded can package of the present invention.

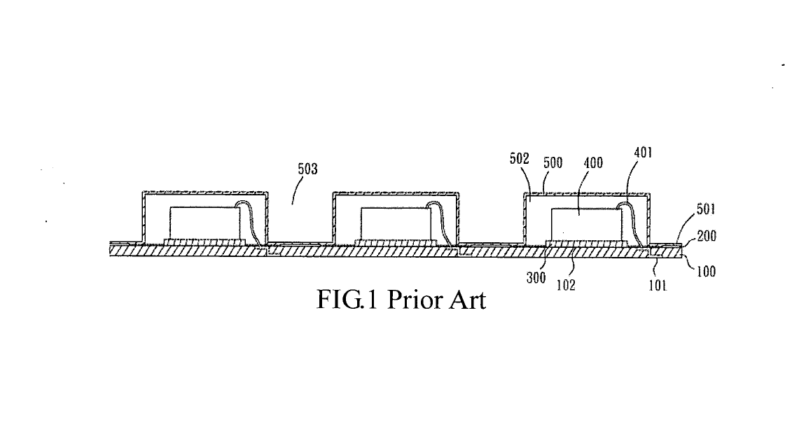

### DETAILED DESCRIPTION OF THE PREFERRED EMBODIMENT

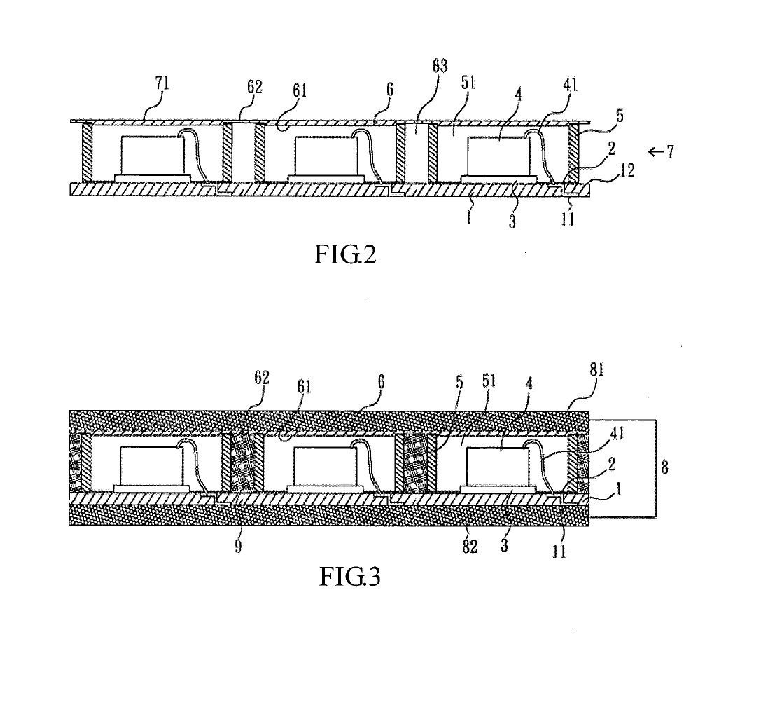

Referring to FIG. 2, the present invention comprises a circuit board 1 to which a circuit board circuit 11 is connected. An adhesive 2 is spread on the top 12 of the circuit board 1 so as to adhere the pre mold cavities 5.

A MEMS die 4 is connected to the circuit board 1 by die adhesive 3.

A conductive wire 41 is welded between the circuit board circuit 11 of the circuit board 1 and the MEMS die 4. By the conductive wire 41, the MEMS die 4 communicates with the circuit board 1.

A pre mold cavity 5 is a hollow cavity with two open ends, the pre mold cavity 5 has a cavity 51 defined therein. The pre mold cavity 5 is individually set and the shape of the pre mold cavity 5 can be square, circular, rectangular and polygonal shape.

A can 6 has a protrusion 61 which is engaged with the pre mold cavity 5. The can supporting bar 62 is connected between any of two adjacent protrusions 61, so that the protrusions 61 and the can supporting bar 62 are continuous connected to each other, and the specific arrangement is convenient for mass production.

When packing the MEMS dies 4, because the MEMS dies 4 easily receive radiation and are contaminated, therefore, the MEMS dies 4 are prepared in a clean room. The circuit board 1 has a circuit board circuit 11 connected thereto and the top 12 of the circuit board 100 is spread with adhesive 2 and die adhesive 3. It is noted that when spreading the adhesive 2 and the die adhesive 3, the circuit board circuit 11 is isolated from the two adhesives 2, 3.

When the MEMS dies 4 are secured to the circuit board 1, the MEMS dies 4, the conductive wires 41 and the circuit board circuit 11 are accommodated in the cavities 51 of the pre mold cavities 5 which are connected to the circuit board 1 by the adhesive 2.

When the pre mold cavity 5 is connected to the circuit board 1 by the adhesive 2 and the MEMS dies 4 are secured to the circuit board 1, the protrusions 61 are engaged with the pre mold cavities 5 to cover multiple MEMS die units 7.

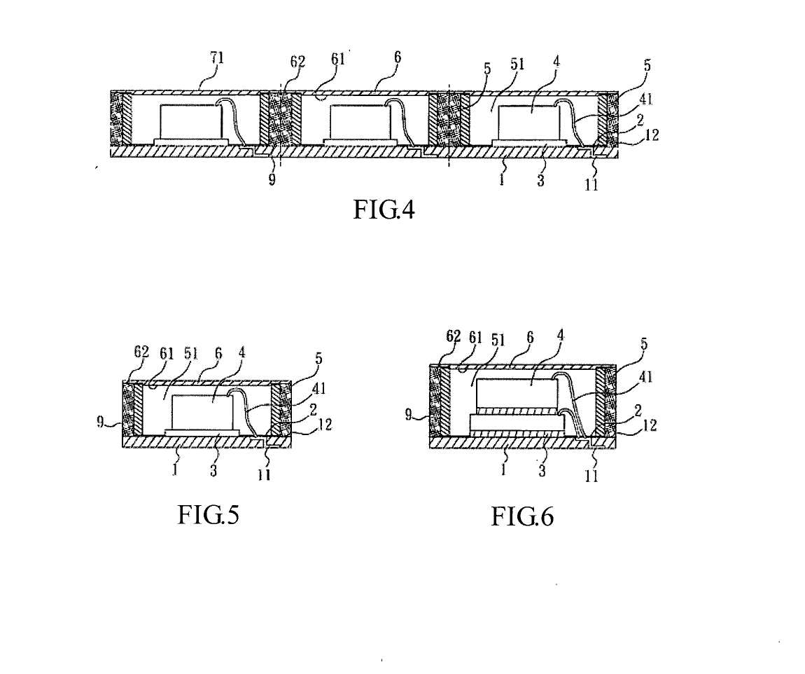

As shown in FIGS. 3 to 5, when the MEMS die units 7 are set, the MEMS die units 7 are put in the down mold 82 of the compound mold 8, and the upper mold 81 of the compound mold 8 is mounted on the tops 71 of the MEMS die units 7. By applying pressure, the cans 6 and the pre mold cavities 5, and the pre mold cavities 5 and the circuit board 1 are more secured. The epoxy compound 9 is then filled in the gaps 63 between the can supporting bars 62 if the cans 6 and the circuit board 1 to pack the MEMS die units 7. The multiple packed the MEMS die units 7 are then cut into several single pieces to obtain the multiple MEMS dies 4 which are small and reliable.

As shown in FIG. 6 which shows the second embodiment of the present invention, the difference from the previous embodiment is that the die adhesive 3 can adhere two or more than two MEMS dies 4 which are allowable to be overlapped in the can cavities 51 between the pre mold cavities 5 and the cans 6 to increase the capacity of the single MEMS die 4.

The processes of the pre molded can package of the present invention are simplified than those of the conventional method, the material required is also saved. The signals for the MEMS dies 4 are more stable than the conventional ones. The manufacturing cost and the material required are reduced, while the efficiency and the yield rate are increased.

While we have shown and described the embodiment in accordance with the present invention, it should be clear to those skilled in the art that further embodiments may be made without departing from the scope of the present invention.

What is claimed is:

1. A pre molded can package comprising:
a circuit board;
a MEMS die;
a conductive wire welded between the circuit board and the MEMS die;
a pre mold cavity being a hollow cavity with two open ends;
a can having a protrusion, two can supporting bars respectively extending from two sides of the protrusion, a MEMS die unit being formed by the circuit board, the MEMS die, the conductive wire, the pre mold cavity and the can, and
the MEMS die unit being packed by a compound mold.

2. The pre molded can package as claimed in claim 1, wherein the circuit board has a circuit board circuit connected thereto.

3. The pre molded can package as claimed in claim 1, wherein the MEMS die is connected to the circuit board by die adhesive.

4. The pre molded can package as claimed in claim 1, wherein the pre mold cavity is connected to the circuit board by adhesive.

5. The pre molded can package as claimed in claim 1, wherein a shaped of the pre mold cavity is square, circular, rectangular and polygonal shape.

6. The pre molded can package as claimed in claim 1, wherein the compound mold comprises an upper mold and a down mold.
